(19) United States
(12) Patent Application Publication
(10) Pub. No.: US 2001/0030849 A1
(43) Pub. Date: Oct. 18, 2001

(54) Device and method of holding an enclosure

(76) Inventor: Juan M. Garnica, Caracus (VE)

Correspondence Address: R. Kent Roberts, Hodgson, Russ, Andrews, Woods & Goodyear LLP, One M&T Plaza, Suite 2000, Buffalo, NY, 14203-2391, US

(21) Appl. No.: 09/734,243

(22) Filed: Dec. 11, 2000

Related U.S. Application Data
(60) Provisional application No. 60/191,080, filed on Mar. 21, 2000.

(51) Int. Cl. G06F 1/16; H05K 5/00; A47B 81/00; A47B 97/00

(52) U.S. Cl. 361/683; 361/679; 312/223.1; 312/223.2; 312/223.3

(57) ABSTRACT

An enclosure is held by devices and a method according to the present invention. In one embodiment of the present invention, two brackets have an extendable arm between them. The brackets may be attached to a piece of furniture. The brackets accommodate an extension of the enclosure, such as a flange or a bar. The flange or bar may be attached to the enclosure, may be an integral part of the enclosure, or may be provided by a device surrounding the enclosure. In another embodiment of the present invention, a device supports the enclosure and is attached to a piece of furniture without using the brackets.

### CROSS CLAIM TO RELATED APPLICATION

Priority is hereby claimed to U.S. Provisional Patent Application No. 60/191,080 filed on Mar. 21, 2000, and is hereby incorporated by this reference.

### BACKGROUND OF THE INVENTION

The present invention relates generally to devices and methods of holding an enclosure.

### SUMMARY OF THE INVENTION

The present invention includes devices and a method of holding an enclosure, such as a computer.

### BRIEF DESCRIPTION OF THE DRAWINGS

For a fuller understanding of the nature and objects of the invention, reference should be made to the following detailed description taken in conjunction with the accompanying drawings, in which:

FIG. 1 is a front view of a device according to the present invention;

FIG. 2 is a top view of the device shown in FIG. 1 with the arms fully extended;

FIG. 3 is a top view of the device shown in FIG. 1 with the arms not fully extended;

FIG. 4 is a perspective view of a C-channel shown in FIG. 1;

FIG. 5 is a perspective view of a piece of furniture showing the C-channel members attached thereto;

FIG. 6 is a perspective view of a piece of furniture showing the C-channel members attached thereto, and showing an enclosure attached to the C-channel members;

FIG. 7 is a perspective view of an enclosure having bars extending therefrom that engage a device according to the present invention, such as the device shown in FIG. 1;

FIG. 8 is a perspective view of a bar shown in FIG. 7;

FIG. 9 is a front view of another device according to the present invention with the arms fully extended;

FIG. 10 is a perspective view of a U-channel shown in FIG. 9;

FIG. 11 is a perspective view of a piece of furniture showing the U-channel members attached thereto;

FIG. 12 is a perspective view of a piece of furniture showing the U-channel members attached thereto, and showing an enclosure attached to the U-channel members;

FIG. 13 is a perspective view of an enclosure an enclosure having flanges attached thereto;

FIG. 14 is a perspective view of a flange shown in FIG. 13;

FIG. 15 is a perspective view of an enclosure with extendable built-in flanges;

FIG. 16 is a front view of the enclosure shown in FIG. 15 with the flanges folded against the enclosure;

FIG. 17 is a front view of the enclosure shown in FIG. 15 with the flanges folded away from the enclosure;

FIG. 18 illustrates a method according to the present invention;

FIG. 19 is an exploded front view of another device according to the present invention;

FIG. 20 is a perspective view of the device shown in FIG. 19, with an enclosure;

FIG. 21 is a perspective view of another device according to the present invention; and

FIG. 22 is an exploded perspective view of the device shown in FIG. 21, an enclosure and a piece of furniture.

### BEST MODE FOR CARRYING OUT THE INVENTION

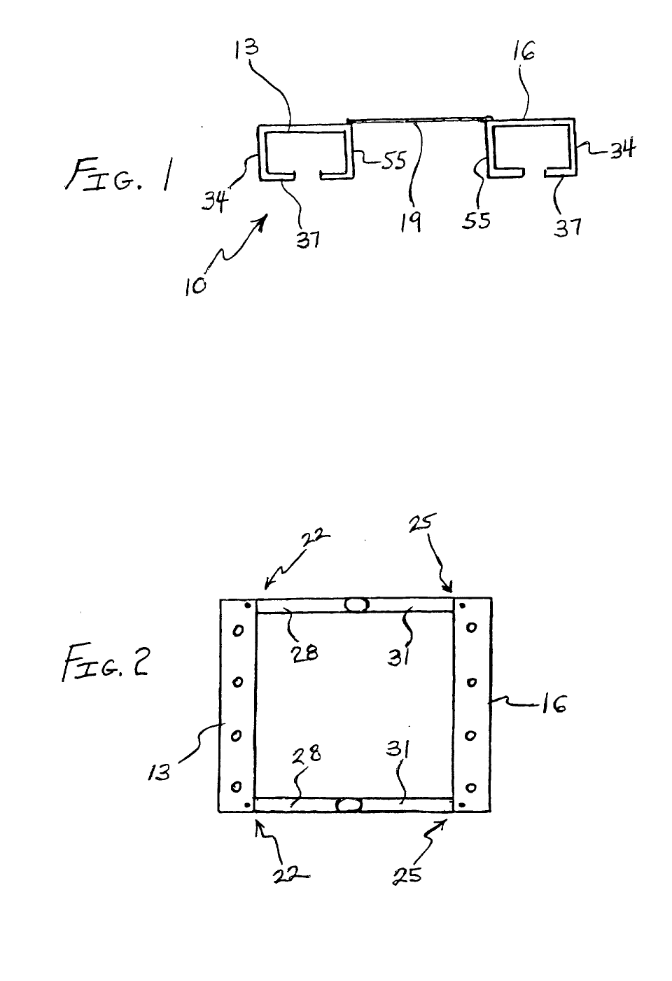

FIGS. 1-3 show an enclosure holding device 10 according to the present invention. The device includes a first bracket 13, a second bracket 16, and an extendable arm 19. The extendable arm 19 has a first end 22 and a second end 25, wherein the first end 22 is joined to the first bracket 13 and the second end 25 is joined to the second bracket. In use, the first bracket 13 and the second bracket 16 are joined to a piece of furniture 26, such as a desk. The brackets 13, 16 may be joined to the piece of furniture 26 by threaded screws 27.

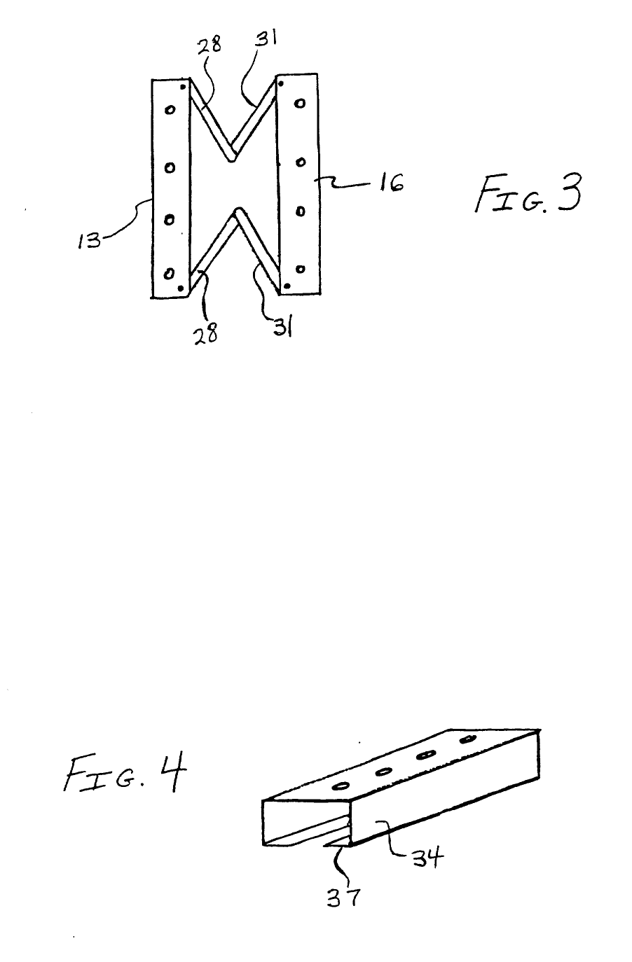

In one embodiment of the present invention, the extendable arm 19 has at least two links 28, 31. See FIGS. 2 and 3. A first link 28 is pivotally connected to the second link 31. In another embodiment of the present invention, the first link 28 is pivotally connected to the first bracket 13 and the second link 31 is pivotally connected to the second bracket 16. Additional links may be provided.

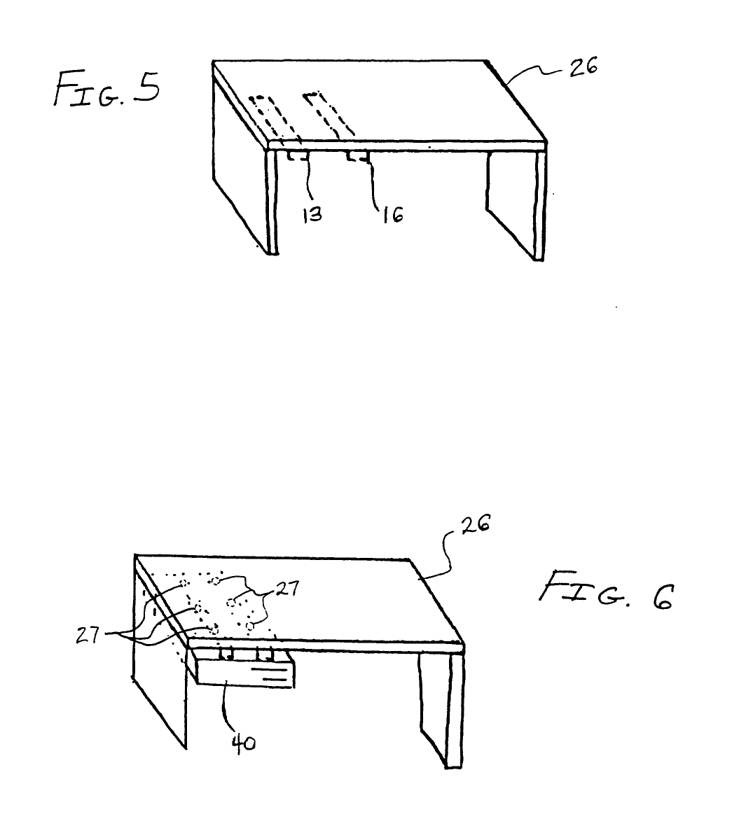

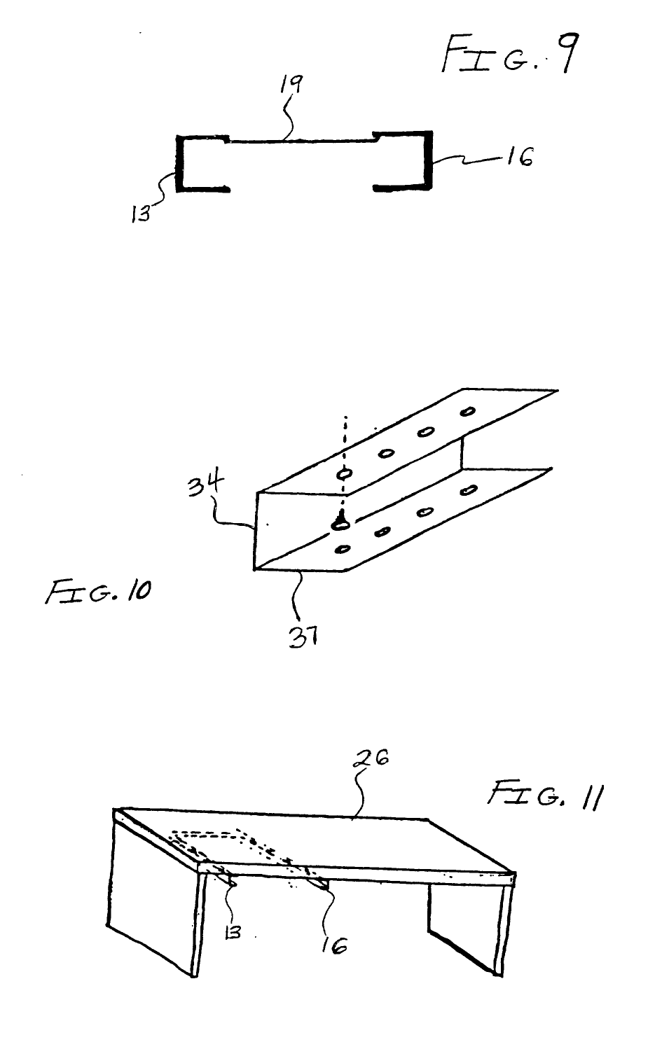

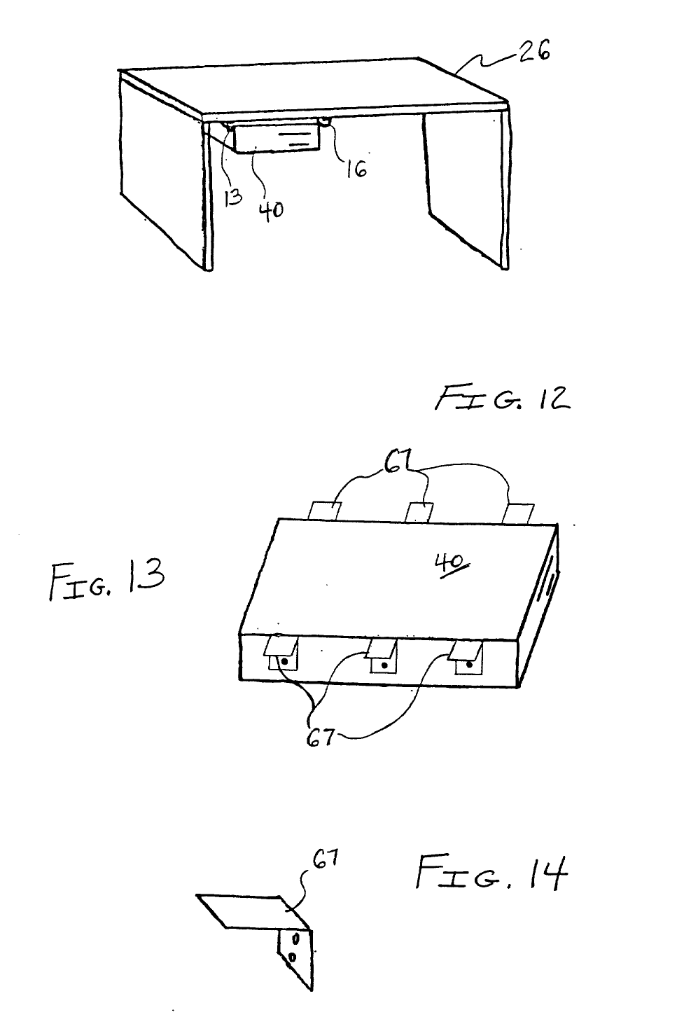

One or more of the brackets 13, 16 has a first member 34, and has a second member 37 connected to the first member 34. The second member 37 is oriented substantially perpendicular to the first member 34. For example, a bracket may be a U-channel (FIGS. 1, 4, 5 and 6) or a C-channel (FIGS. 9, 10, 11 and 12).

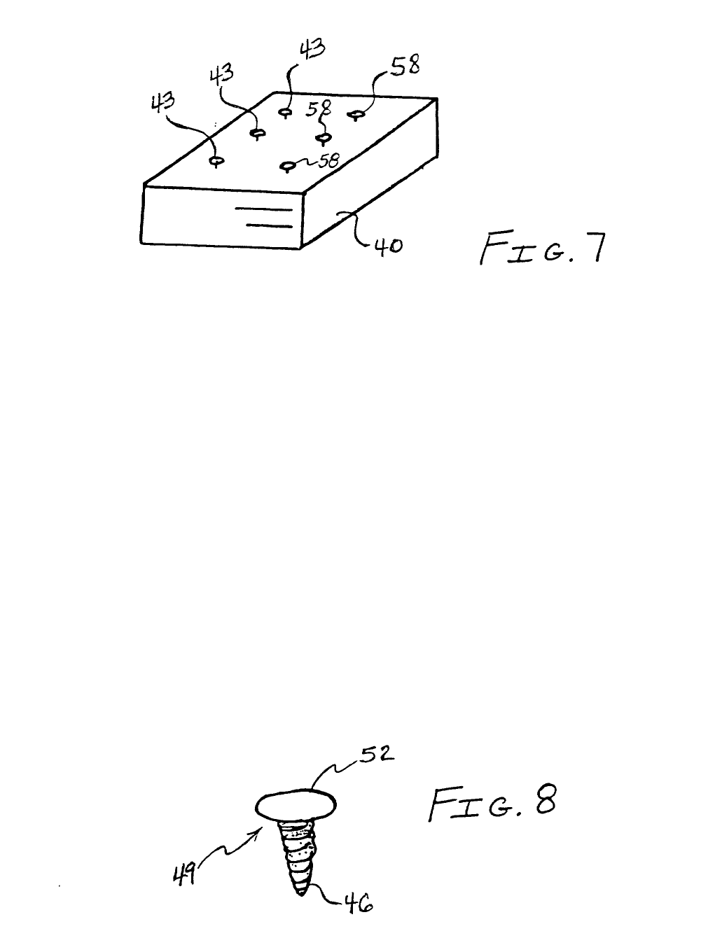

An enclosure 40 is joined to the enclosure holding device 10. The enclosure 40 may have a first bar 43 having a first end 46 and a second end 49, wherein the first end 46 of the first bar 43 is joined to the enclosure 40. The first end 46 may be threaded into the enclosure 40 or the first end 46 may be welded, glued or otherwise affixed to the enclosure 40. The second end 49 of the first bar 43 is received in the first bracket 13 to support the enclosure 40 from the first bracket 13 via the first bar 43. To facilitate support of the enclosure 40, the first bar 43 may be provided with an enlarged head 52 on the second end 49. See FIGS. 7 and 8. The enlarged head 52 resides within and in close proximity to the first member 34 and a third member 55 opposing the first member 34 and thereby prevents the enclosure 40 from rocking.

A second bar 58 may be provided in a manner similar to the first bar 43 having a first end 46 and a second end 49. The first end 46 is joined to the enclosure 40 and the second end 49 resides within and in close proximity to the first member 34 and the third member 55 of the second bracket 16. It will now be recognized that the enlarged head 52 of the first bar 43 is slidable within the first bracket 13, and the enlarged head 52 of the second bar 58 is slidable within the second bracket 16 so that the enclosure 40 is selectively connected to the enclosure holding device 10.

The enclosure 40 may be a case having electrical components therein. For example, the enclosure 40 may house a microprocessor or an information storage device, such as a computer hard drive.

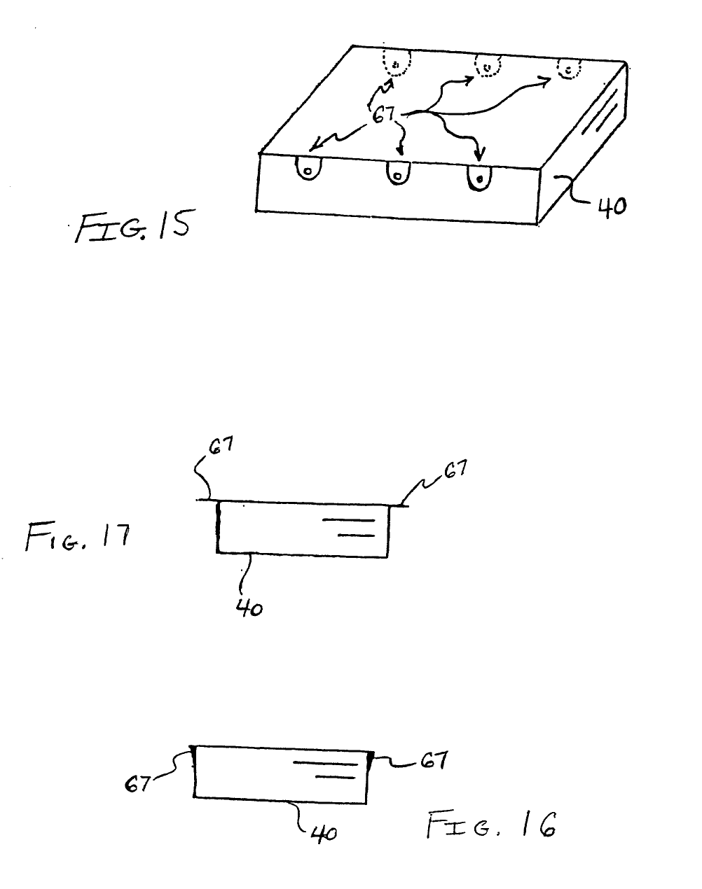

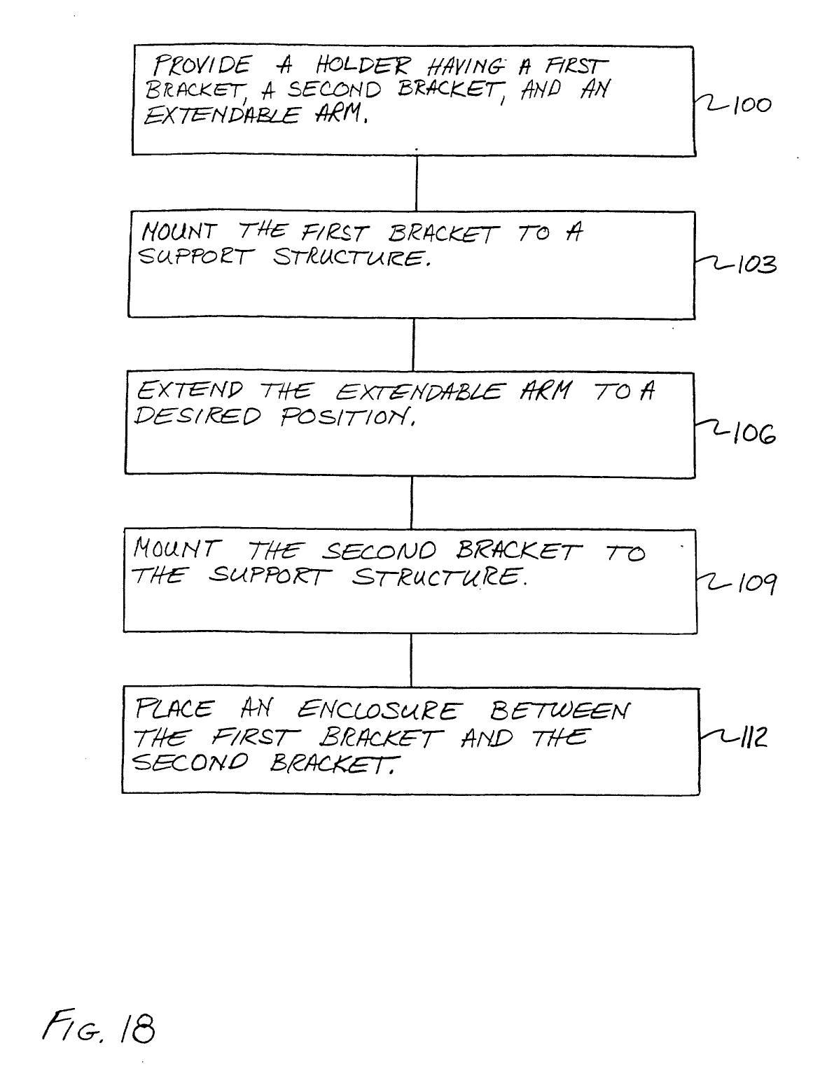

In another embodiment of the present invention, the enclosure 40 may have one or more flanges 67 extending from the enclosure 40 as shown in FIGS. 13-17. The flanges 67 may be selectively extendable from a first position, as shown in FIGS. 15 and 16, proximate to the enclosure 40, to a second position shown in FIG. 17 where one end of the flange is distal from the enclosure 40.

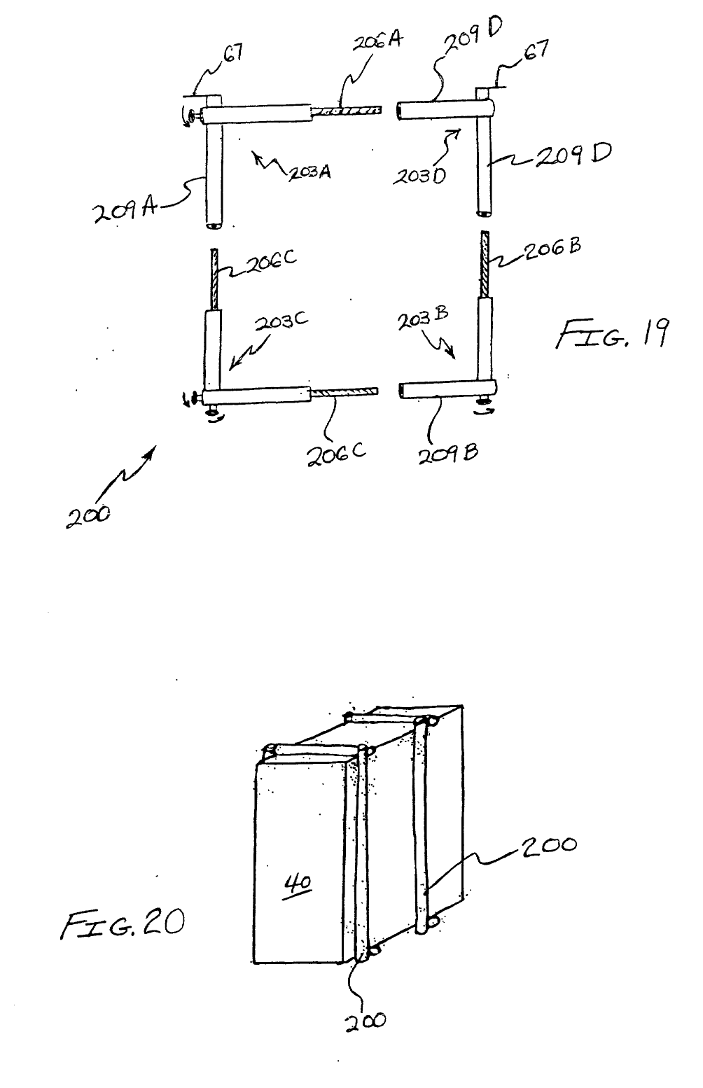

FIG. 18 illustrates aspects of a method of holding an enclosure according to the present invention. A holding device is provided 100. The holding device has a first bracket, a second bracket, and an extendable arm. The first bracket, the second bracket and the extendable arm may be similar to those described above. The first bracket is mounted 103 to a support structure, and the extendable arm is extended 106 to a desired position. Then the second bracket is mounted 109 to the support structure. An enclosure is placed 112 between the first bracket and the second bracket. The support structure may be a piece of furniture, such as a desk.

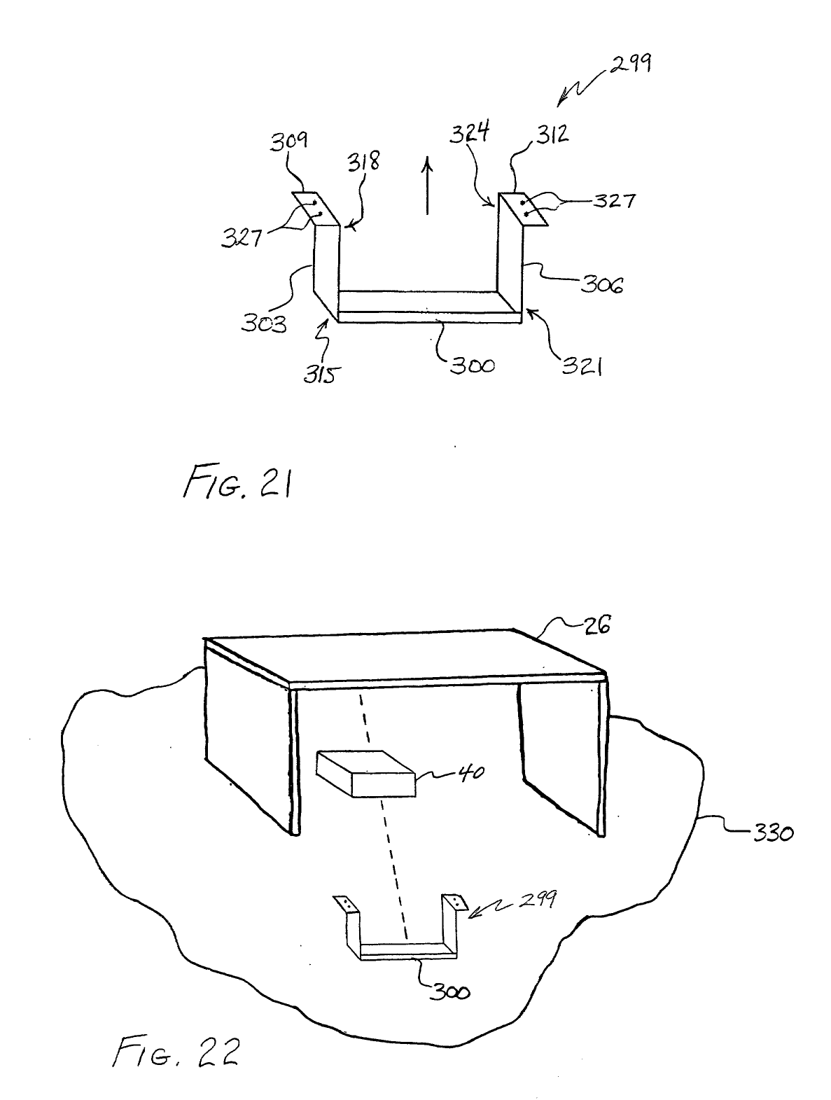

FIGS. 19 and 20 show another enclosure holding device 200 according to the present invention. The holding device 200 has four braces 203. A first brace 203A has a bar 206A and a casing 209A, and a second brace 203B has a bar 206B and a casing 209B. A third brace 203C has two bars 206C, one of the bars 206C being matable with the casing 209A of the first brace 203A and the other of the bars 206C being matable with the casing 209B of the second brace 203B. A fourth brace 203D has two casings 209D, one of the casings 209D being matable with the bar 206A of the first brace 203A, and the other of the casings 209D being matable with the bar 206B of the second brace 203B. One or more of the casings 209 may be internally threaded for engaging corresponding external threads of a mating rod 206. Two of the braces 203, for example braces 203A and 203D, each have a flange 67 for engaging an enclosure holding device, such as the enclosure holding device 10 shown in FIG. 9. In lieu of a flange 67, two of the braces 203 may have a bar, similar to the bar 43 (shown in FIGS. 7 and 8) for engaging an enclosure holding device, such as the enclosure holding device 10 shown in FIG. 1. It will now be recognized that the enclosure holding device 200 is adjustable in size to accommodate enclosures 40 of different sizes.

FIGS. 21 and 22 show a holder 299 according to the present invention that includes a holding surface 300, a first extension 303, a second extension 306, a first flange 309 and a second flange 312. The first extension 303 has a first end 315 and a second end 318, wherein the first end 315 of the first extension 303 is attached to the holding surface 300, and the first extension 303 extends from the holding surface 300 in a first direction indicated by the arrow in FIG. 21. The first flange 309 is attached to the second end 318 of the first extension 303. The second extension 306 has a first end 321 and a second end 324, wherein the first end 321 of the second extension 306 is attached to the holding surface 300, and the second extension 306 extends from the holding surface 300 in the first direction. The second flange 312 is attached to the second end 324 of the second extension 306.

The first flange 309 has one or more orifices 327 therethrough. The second flange 312 may also have one or more orifices 327 therethrough for receiving a fastener. Each of orifices 327 may be sized to accommodate a fastener, such as a nail or a screw. When the fastener extends through the orifice 327, it may extend into a piece of furniture, such as a desk, to fix the first flange 309 relative to the desk. For example, the first flange 309 may be fixed relative to the piece of furniture 26 so that the holding surface 300 resides between a portion of the piece of furniture 26 and a floor 330 supporting the piece of furniture 26. The enclosure 40 may be placed on the holding surface 300. The enclosure 40 may be held by one or more of the holders 299 shown in FIGS. 21 and 22.

Although the present invention has been described with respect to one or more particular embodiments, it will be understood that other embodiments of the present invention may be made without departing from the spirit and scope of the present invention. Hence, the present invention is deemed limited only by the appended claims and the reasonable interpretation thereof.

What is claimed is:

1. An enclosure holding device, comprising:
a first bracket;
a second bracket; and
an extendable arm having a first end and a second end, wherein the first end is joined to the first bracket and the second end is joined to the second bracket.

2. The device of claim 1, wherein the extendable arm is comprised of a first link and a second link, wherein the first link is pivotally connected to the second link.

3. The device of claim 1, wherein the extendable arm is comprised of a first link and a second link, wherein the first link is pivotally connected to the first bracket and the second link is pivotally connected to the second bracket.

4. The device of claim 1, wherein at least one of the brackets is a U-channel.

5. The device of claim 1, wherein at least one of the brackets is a C-channel.

6. The device of claim 1, wherein at least one of the brackets has a first member, and has a second member connected to the first member, wherein the second member is oriented substantially perpendicular to the first member.

7. An enclosure and an enclosure holding device, comprising:
an enclosure;
a first bar having a first end and a second end, wherein the first end of the first bar is joined to the enclosure; and
a first bracket capable of receiving the second end of the first bar.

8. The enclosure and holding device of claim 7, wherein the first bar has an enlarged head on the second end.

9. The enclosure and holding device of claim 7, further comprising a second bar, wherein the second bar has a first end and a second end, wherein the first end of the second bar is joined to the enclosure, and further comprising a second bracket capable of receiving the second end of the second bar.

10. The enclosure and holding device of claim 9, further comprising an extendable arm having a first end and a second end, wherein the first end of the extendable arm is joined to the first bracket and the second end of the extendable arm is joined to the second bracket.

11. The enclosure and holding device of claim 10, wherein the extendable arm is comprised of a first link and a second link, wherein the first link is pivotally connected to the second link.

12. The enclosure and holding device of claim 10, wherein the extendable arm is comprised of a first link and a second link, wherein the first link is pivotally connected to the first bracket and the second link is pivotally connected to the second bracket.

13. The enclosure and holding device of claim 10, wherein at least one of the brackets is a U-channel.

14. The enclosure and holding device of claim 10, wherein at least one of the brackets is a C-channel.

15. The enclosure and holding device of claim 7, wherein the enclosure is a case having electrical components therein.

16. The enclosure and holding device of claim 15, wherein the electrical components included a microprocessor.

17. The enclosure and holding device of claim 15, wherein the electrical components included an information storage device.

18. An enclosure and an enclosure holding device, comprising:
an enclosure having a first flange extending therefrom; and
a first bracket capable of receiving an end of the first flange.

19. The enclosure and holding device of claim 18, further comprising a second flange and a second bracket capable of receiving an end of the second flange.

20. The enclosure and holding device of claim 19, further comprising an extendable arm having a first end and a second end, wherein the first end of the extendable arm is joined to the first bracket and the second end of the extendable arm is joined to the second bracket.

21. The enclosure and holding device of claim 19, wherein the extendable arm is comprised of a first link and a second link, wherein the first link is pivotally connected to the second link.

22. The enclosure and holding device of claim 19, wherein the extendable arm is comprised of a first link and a second link, wherein the first link is pivotally connected to the first bracket and the second link is pivotally connected to the second bracket.

23. The enclosure and holding device of claim 19, wherein at least one of the brackets is a U-channel.

24. The enclosure and holding device of claim 19, wherein at least one of the brackets is a C-channel.

25. The enclosure and holding device of claim 18, wherein the enclosure is a case having electrical components therein.

26. The enclosure and holding device of claim 25, wherein the electrical components included a microprocessor.

27. The enclosure and holding device of claim 25, wherein the electrical components included an information storage device.

28. A method of holding an enclosure, comprising:
providing a holding device having a first bracket, a second bracket, and an extendable arm having a first end and a second end, wherein the first end is joined to the first bracket and the second end is joined to the second bracket;
mounting the first bracket to a support structure;
extending the extendable arm to a desired position;
mounting the second bracket to the support structure;
placing an enclosure between the first bracket and the second bracket.

29. The method of claim 28, wherein the support structure is a piece of furniture.

30. The method of claim 29, wherein the piece of furniture is a desk.

31. The method of claim 28, wherein at least one of the brackets has a first member, and has a second member connected to the first member, wherein the second member is oriented substantially perpendicular to the first member, and the enclosure has a bar extending from the enclosure to the bracket.

32. The method of claim 28, wherein at least one of the brackets has a first member, and has a second member connected to the first member, wherein the second member is oriented substantially perpendicular to the first member, and the enclosure has a flange extending from the enclosure to the bracket.

33. A holder, comprising:
a first brace having a bar and a casing;
a second brace having a bar and a casing;
a third brace having two bars, one of the bars being matable with the casing of the first brace and the other of the bars being matable with the casing of the second brace; and
a fourth brace having two casings, one of the casings being matable with the bar of the first brace, and the other of the casings being matable with the bar of the second brace.

34. The holder of claim 33, wherein the casing of the first brace is internally threaded, and the corresponding matable bar of the third brace is externally threaded.

35. The holder of claim 33, wherein one of the casings of the fourth brace is internally threaded, and the corresponding matable bar is externally threaded.

36. The holder of claim 33, wherein one of the bars of the third brace is externally threaded, and the corresponding matable casing is internally threaded.

37. The holder of claim 33, wherein each of the casings is internally threaded and each of the bars is externally threaded.

38. A holder, comprising:
holding surface;
a first extension having a first end and a second end, wherein the first end of the first extension is attached to the holding surface, and the first extension extends from the holding surface in a first direction;
a first flange attached to the second end of the first extension;
a second extension having a first end and a second end, wherein the first end of the second extension is attached to the holding surface, and the second extension extends from the holding surface in the first direction;
a second flange attached to the second end of the second extension.

39. The holder of claim 38 wherein the first flange has an orifice therethrough for receiving a fastener.

40. The holder of claim 39, further comprising a fastener extending through the orifice.

41. The holder of claim 39, wherein the fastener extends into a piece of furniture and fixes the first flange relative to the piece of furniture.

42. The holder of claim 41 wherein the holding surface resides between a portion of the piece of furniture and a floor supporting the piece of furniture.

43. The holder of claim 38, further comprising a computer resting on the holding surface.
